(19) United States
(12) Patent Application Publication
(10) Pub. No.: US 2009/0202718 A1
(43) Pub. Date: Aug. 13, 2009

(54) PASSIVATION OF POROUS CERAMIC ARTICLES

(76) Inventors: Willard Ashton Cutler, Big Flats, NY (US); Paul John Shustack, Elmira, NY (US); Tinghong Tao, Big Flats, NY (US); Jianguo Wang, Horseheads, NY (US)

Correspondence Address: CORNING INCORPORATED, SP-TI-3-1, CORNING, NY, 14831, US

(21) Appl. No.: 12/423,304

(22) Filed: Apr. 14, 2009

Related U.S. Application Data
(63) Continuation of application No. 11/998,239, filed on Nov. 29, 2007.

(51) Int. Cl. C23C 16/44

(52) U.S. Cl. 427/230; 118/715

(57) ABSTRACT

An apparatus and method to passivate porous ceramic articles containing microcracks as described herein. The method includes circulating a fluid including a passivator through the porous ceramic article and depositing at least a portion of the passivator on the porous ceramic article.

### BACKGROUND

The disclosure relates to an apparatus and method of passivating a porous ceramic article. More particularly, the disclosure concerns preserving microcracks in coated, porous ceramic articles.

### SUMMARY

The disclosure provides an apparatus and a method to passivate porous ceramic articles containing microcracks. The method protects microcracks and maintains the coefficient of thermal expansion (CTE) of the article. In embodiments, the method can, for example, be used in continuous operations, can improve operating efficiency, can use less polymer, can reduce volatile emissions, can reduce the number of processing steps, or a combination thereof. In catalyst support articles, the method can better direct catalyst placement and reduce the in-use pressure drop across the support articles.

### BRIEF DESCRIPTION OF THE DRAWING

FIG. 1 is a block diagram schematic of an apparatus for performing the passivation method, in embodiments of the disclosure.

### DETAILED DESCRIPTION

Various embodiments of the disclosure will be described in detail with reference to drawings, if any. Reference to various embodiments does not limit the scope of the invention, which is limited only by the scope of the claims attached hereto. Additionally, any examples set forth in this specification are not limiting and merely set forth some of the many possible embodiments for the claimed invention.

The indefinite article “a” or “an” and its corresponding definite article “the” as used herein means at least one, or one or more, unless specified otherwise.

“Include,” “includes,” or like terms means including but not limited to.

“About” modifying, for example, the quantity of an ingredient in a composition, concentrations, volumes, process temperature, process time, yields, flow rates, pressures, and like values, and ranges thereof, employed in describing the embodiments of the disclosure, refers to variation in the numerical quantity that can occur, for example, through typical measuring and manipulation procedures; through inadvertent error in these procedures; through differences in the manufacture, source, or purity of starting materials or ingredients used to carry out the methods; and like considerations. The term “about” also encompasses amounts that differ due to, for example, aging of a formulation having a particular initial concentration, mixture, topography, or morphology, and amounts that differ due to processing a formulation with a particular initial concentration, mixture, topography, or morphology. Whether modified by the term “about” the claims appended hereto include equivalents to these quantities.

“Optional” or “optionally” or like terms generally refer to, for example, that the subsequently described event or circumstance can or cannot occur, and that the description includes instances where the event or circumstance occurs and instances where it does not.

“Consisting essentially of” in embodiments refers, for example, a method of passivating a porous ceramic article comprising microcracks as defined herein, and can include the components or steps listed in the claim, plus other components or steps that do not materially affect the basic and novel properties of the composition, article, apparatus, system, and method of making and use of the disclosure, such as a particular reactant, a particular additive or ingredient, a particular agent, a particular surface modifier or condition, or like structure, material, process, or computational variable selected.

In embodiments, the method passivates a porous ceramic article having microcracks. The porous ceramic article can include a honeycomb body. The method relies on propensity of a fluid to wick to smaller radius openings, such as the microcracks. The method includes contacting the porous ceramic article and the fluid. Contacting can include circulation of the fluid through the porous and more preferably also through the interior walls and exposed faces of the article. The article may be, for example, a catalyst support or filter such as diesel particulate filter. Circulation refers to passing the fluid through the porous ceramic article, and can include circulating the fluid past, into, around, or through the article. Circulation includes passing through an exposed face of the porous ceramic article and out another exposed face, but can also include penetration into a surface layer of the porous ceramic article.

In embodiments, the method can include using or forming a fluid having a passivator comprising, for example, a condensable component. A passivator includes any material, for example, as described herein, other than water, which can fill, occupy or block the microcracks prior to treating with a washcoat. The fluid can be in the form of, for example, a solution, mixture, or suspension, and may comprise one or more components. Single component fluids may be formed, for example, by boiling or atomization. The fluid can also include a plurality of components including the passivator, such as a condensable component, and a carrier fluid. Multiple-part fluids include, for example, solutions, mixtures, or suspensions. A solution can be produced by, for example, dissolving a passivator in a carrier fluid that is a suitable solvent. Dissolving may occur, such as, by evaporating the passivator in a suitable gas. A mixture can include, for example, any combination of discrete particles or phases. A suspension can comprise liquid or solid particles suspended in a gas or liquid. A suspension can include, for example, an aerosol, such as a vapor, fog, mist, smoke, and like dispositions, and combinations thereof.

An article's coefficient of thermal expansion (CTE) affects its resistance to thermal shock. An article with a lower CTE tends to have greater resistance to thermal shock than a similar article with a higher CTE. Microcracks have been known to reduce the apparent, or bulk, CTE of ceramic articles. Microcracks are intentionally introduced into the article and act like expansion buffers to reduce the bulk CTE and improve the thermal shock resistance of the article. The dimensions of microcracks can be, for example, from about 0.1 to about 0.4 microns wide and from about 30 to about 300 microns long. Microcracks tend to be very stable and tend not to change dimensions over many thermal cycles. However, microcracks can be susceptible to composition, processing, chemical treatment, and like conditions.

For example, porous ceramic articles having microcracks are used as catalyst supports in various applications. The catalyst is often applied as a washcoat, and the washcoat can comprise a metal catalyst. Particles in the washcoat can enter the microcracks and prevent the microcracks from closing during heating. This increases the CTE of the article and decreases thermal shock resistance. Several methods for passivating porous ceramic articles are known. Passivation preserves microcracks during application of a washcoat so that the microcracks can function as expansion buffers when the article is heated. In embodiments, passivation can be accomplished by, for example, dipping the porous ceramic article into a solution comprising a soluble polymer, such as a crosslinkable polymer, blowing out the excess solution, and thermally drying to evaporate the liquid vehicle and to crosslink the polymer.

An organic compound, such as methylcellulose, may be applied to the article before application of the catalyst washcoat. The organic compound coats the surface of the article, including the microcracks, and prevents the washcoat from filling the microcracks. Firing the article bums off the organic compound leaving empty microcracks and preserving a low CTE. Alternatively, a water soluble, high molecular weight, organic pre-coat may be applied to the article and the washcoat may be subsequently deposited over the pre-coat. The high molecular weight pre-coat can be burned off leaving empty microcracks.

The article may be pre-coated with an aqueous buffer solution and later coated with a slurry comprising, for example, a gel-forming agent. The buffer solution fills the microcracks, and, for example, can consist essentially of water and a buffering agent. The slurry gels on contact with the buffer solution, and creates plugs over the microcracks. Firing removes water from the buffer solution and leaves essentially empty microcracks. The buffer solution is chosen to match the particular gel-forming agent. An example of a buffer solution/slurry pair includes: a pH 7 buffer solution comprising water, monobasic potassium phosphate, and sodium hydroxide; and a pH 3 slurry of alumina.

The pre-coat may even comprise a liquid vehicle, such as water, and a water-soluble, thermally cross-linkable, thermally pyrolyzable, hydrocarbon polymer. The pre-coat can be applied to the article and dried to remove the liquid vehicle. The polymer crosslinks during drying.

Vapor deposition techniques that form a permanent contiguous polymer coating onto a surface of an article are known. The coating affects surface active reactions, such as corrosion resistance, water repellency, and biocompatibility. A polymer precursor can be applied to the article and polymerized to produce a thin polymer film on the article. The polymer can be formed using, for example, thermal or radiation-induced initiators. Such films find utility as anti-corrosion coatings on metal products, for example, epoxy coating on pipes. Siloxanes have been vaporized, condensed on an article, and subsequently polymerized in order to produce a water-repellant article. Alternatively, vapor deposition of a polymer precursor has been used to improve bioactivity or biocompatibility of metal or ceramic articles. Di-functional epoxide monomers and telechelic epoxide polymers have been vapor deposited on inorganic substrates, such as glass, to produce clear, protective coatings. Frequently, coating deposition can be accomplished under vacuum which facilitates evaporation of the polymer precursor. The polymer precursor may be heated to accelerate evaporation. High levels of polymer precursor may be required. While vapor deposition typically affects surface active properties of an article, it does not address passivation of microcracks, which affects bulk properties of the article.

Passivation techniques for ceramic articles can be very costly. The techniques tend to be batch processes in which the passivating layer is applied indiscriminately on exposed surfaces of the articles.

In embodiments, the disclosed passivation method can provide one or more superior aspects including, for example:
faster loading of the passivator, often in a few seconds;
elimination of a drying step;
elimination of a “blow-out” step in which excess passivation solution is removed from the article;
faster polymer cross-link chemistry;
no pre-reaction is necessary thus the passivator may be used neat;
no vacuum system required;
reduced passivator loading;
less pollution and decomposition products generated on burnout (calcination);
higher washcoat/catalyst loading compared to articles passivated using known methods;
or a combination thereof.

The disclosure provides a method of passivating a porous ceramic article having microcracks. The method includes applying a passivating material preferentially at the microcracks. Known passivation techniques typically use substantially more polymer, up to at least around 3 wt. %, and consequently require longer drying, curing, and calcining cycles; these aspects can result in higher costs for capital equipment, increased energy requirements, and increased emissions.

The disclosed method includes contacting a fluid and a porous ceramic article, for example, by passing a fluid through or across a porous ceramic article containing microcracks. The fluid includes a passivator, and can also include a carrier fluid. The fluid can be at a first temperature which is higher than a second temperature of the porous ceramic article. The temperature difference is sufficient for condensation of at least a portion of the fluid. Preferably, the passivator will condense from the fluid. The fluid, that is, the carrier fluid and/or the passivator, will preferentially condense around or in the microcracks. The carrier fluid can be any solvent for the passivator but is preferably a gas, such as air or water vapor. The passivator can include, for example, an organic solid or liquid, for example, glycerin, an unsaturated or condensable monomer, an oligomer, or a polymer.

In embodiments, the solution can include a fluid comprising a discontinuous phase of passivator suspended in a carrier fluid comprising a gas or liquid. Particles of the discontinuous phase are generally small, that is, less than about 5 microns in diameter. The carrier fluid can form a solution with the passivator. The passivator can include any material that can plug the microcracks upon condensation, and can include any liquid or solid provided the passivator is capable of being transported by the fluid and volatized at elevated temperatures to leave substantially empty microcracks. Preferably, the majority of the fluid, that is, the carrier fluid, does not remain in or on the porous ceramic article.

In embodiments, the fluid can comprise a carrier fluid solvent and a solute of the dissolved passivator. The carrier fluid solvent can include a gas, such as air, an inert gas or water vapor, and the passivator includes an evaporable liquid such as glycerin. The gas passes over the evaporable liquid so that at least a portion of the evaporable liquid will evaporate into the gas to form a solution, that is, the fluid. Preferably, the gas can be heated to facilitate evaporation of the evaporable liquid. The heated solution is directed to and circulated through the porous ceramic article. The porous ceramic article can be at least initially cooler than the warm or heated solution. Contact of the heated solution with the cool article causes at least a portion of the passivator to fall out of solution and deposit on the article. The passivator preferentially collects in and around microcracks. Advantageously, the solution heats up the porous ceramic article to limit the amount of passivator that will collect on the porous ceramic article. After circulating through the porous ceramic filter, the fluid optionally can be re-circulated through the porous ceramic filter. Re-circulation preferably includes reheating the fluid and passing the heated fluid over the vaporizable or evaporable liquid before circulating through the porous ceramic filter.

The fluid can include, for example, a heated gas and the passivator can include, for example, a polymer. Examples of the heated gas and the passivator include water vapor and a methylcellulose ether polymer. The heated gas can be at a first higher temperature. The heated gas can pass over and absorb the polymer. The gas may become saturated with the polymer but typically the amount of polymer in the gas is less than about 1 wt. %. The polymer-containing gas can pass through a porous ceramic article. The porous ceramic article can be initially at a second lower temperature. The first higher temperature is initially higher than the second lower temperature. As the heated, polymer-containing gas contacts the cooler ceramic article, the polymer condenses on the ceramic article primarily in an around microcracks. The heated gas eventually heats the ceramic article, such as a filter, to a temperature that does not favor condensation. Until the non-condensing temperature is reached, the article will accumulate a small amount of polymer, generally less than about 1 wt. %. The article can be removed from the heated gas, dried, and cured.

Preferably, an apparatus used for the method can be heated so that the passivator does not substantially condense anywhere but on the porous ceramic article. The solvent may be re-used along with any passivator that remains in the solution and has not condensed on the article. Re-use can include re-circulating the fluid through the porous ceramic article.

In embodiments, the fluid includes an atomized passivator and the fluid can be formed by passing a stream of heated gas or liquid through an atomized passivator. Atomization can be accomplished by any known methods. The solution can then be circulated through the porous ceramic article. Some of the atomized passivator condenses at the microcracks. Typically, less than about 1 wt. % passivator is needed to be effective. The direction at which the heated fluid approaches the article can influence the effectiveness of passivation. For example, an article comprising a porous ceramic filter may have the heated fluid approach from the rear of the filter so that greater passivation protection takes place in the rear where thermal shock can be more problematic.

In embodiments, the passivator can include a chemically reactive compound, such as a monomer, oligomer or polymer precursor. The reactive compound may require one or more components. The reactive compound can include a component that polymerizes in the presence of an initiator. The initiator can be another compound or can be electromagnetic radiation, electron beam, heat, or like agents. For example, the passivator can include a monomer that is initiated with ultraviolet radiation, that is, a light-sensitive or light-activated initiator. Alternatively, the passivator can include a monomer that is polymerized with a thermal initiator, that is, a heat-sensitive or heat-activated initiator. FTIR results indicate complete cure of the reactive compound can occur in as little as 10 to 45 minutes at 100° C. In contrast, known cure methods can require a cure time of about 20 hours at 100° C.

In embodiments, the method of the disclosure can include generating a fluid comprising a reactive compound. The compound can be polymerizable or co-polymerizable. The reactive compound can include, for example, at least a first reactive component such as a monomer, an oligomer, or a low molecular weight polymer. The fluid circulates through the filter, and some of the reactive compound condenses in the porous ceramic filter. The first reactive component can react to passivate the porous ceramic article. In an optional second step, a second fluid comprising a second reactive component can be circulated through the ceramic article after condensation of the first reactive component from the first fluid. The second reactive component can be selected to react with the first reactive component to form a polymer that protects the microcracks of the filter.

In embodiments, a passivator can comprise a component that undergoes polymerization during or after condensation. Examples include polymers and copolymers of urethane, epoxy, urea-formaldehyde, vinyl, alkoxysilane, oxetane, aziridine, phenolics, vinyl ethers, vinyl esters, acrylates, methacrylates, acrylamides, styryls, allyls, vinyl amide, vinyl amines, maleimides, maleates, itaconates, crotonates, anhydrides, and like monomers, or combinations thereof. Alternative or additional polymer types and chemistries can include, for example, polyester, polyamide, polyimide, polyether, carbodiimide, or like polymers, and combinations thereof. In embodiments, the passivator can include, for example, an epoxy polymer formed from an organic diamine and an organic ether, such as an alkylene glycol diamine and an alkylene glycol diglycidyl ether.

In embodiments, the passivator, such as a polymerizable or crosslinkable component, can use a thermal or radiation-sensitive initiator. The initiator can be transported to the reactive compound after the reactive compound has condensed on the ceramic article. Alternatively, the initiator can be condensed before the reactive compound, simultaneously with the reactive compound, or the initiator and reactive compound may be mixed together and then condensed onto the article.

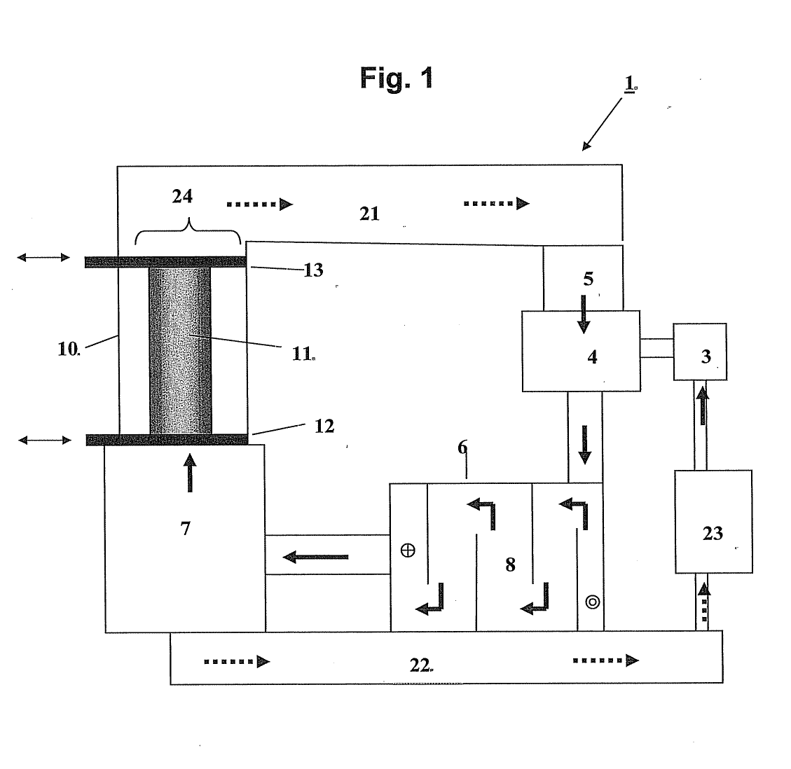

FIG. 1 shows, in embodiments, an apparatus useful for passivating a ceramic green body with a first fluid comprising a first reactive component and a second fluid comprising a second reactive component. The first and second reactive components can react to form the passivator. The apparatus 1 includes a mist generator comprising a pump 3 and an atomizer or aerosolizer 4, a circulator 5, and a holder 10. The holder 10 can include a chamber. The holder secures, such as by containing, the ceramic green body 11. The pump 3 pumps the first fluid comprising a first reactive component through the aerosolizer such as atomizer 4 to form an aerosol such as a mist. The aerosol can comprise a first reactive component and a carrier fluid. Alternatively, the aerosol can consist essentially of the first reactive component if the neat reactive component can be formed into an aerosol. The circulator 5 can include a fan, and moves the aerosol to the holder 10 and through the ceramic green body 11.

The aerosolizer or mist generator can optionally include a nebulizer 6. The mist as produced by the atomizer 4 can include a range of particle sizes. The nebulizer 6 defines a circuitous path 8 along which small atomized particle sizes can coalesce and larger atomized particle sizes can condense. The circuitous path 8 can include a plurality of stages. The processes of coalescence and condensation produce a mist with a more uniform particle size. The mist generator may also include a homogenizer 7. The homogenizer 7 aligns the mist in a plug flow configuration before the mist enters the holder 10. Plug flow refers to movement of a material as a unit without shearing within the mass. The plug of mist will move evenly through the middle and periphery of the ceramic green body 11. If desired, the inlet and outlet ends of the ceramic green body 11 can optionally be rotated to ensure uniform condensation of the fluid. This is especially useful with large ceramic green bodies. Rotation can be accomplished by flipping the ceramic green body or reinserting in the holder upside down.

The holder 10 can be isolated from the mist generator by, for example, at least one movable shutter 12 that prepares the holder for receipt of the mist. Preparation includes, for example, evacuation or an inert gas purge that removes potentially dangerous or explosive materials, such as oxygen, from the holder 10. The shutter 12 can be opened to allow the mist into the holder. If a homogenizer 7 is used, the shutter can be opened when the holder has been prepared and the homogenizer has aligned the mist. The circulator 5 forces the mist through the ceramic green body 11. The shutter 12 can be closed, for example, when a sufficient amount of the mist condenses on the ceramic green body 11.

Optionally, the apparatus 1 can include a recycler. The recycler can include a mist recycler 21 and/or a drain 22. The mist recycler 21 can recycle mist that has passed through the ceramic green body 11. The mist recycler 21 includes a hood manifold 24 capable of a fluid connection with the holder 10. The hood manifold 24 collects mist as it exits the holder 10. The holder 10 can include a second movable shutter 13 that separates the holder 10 from the mist recycler 21 unless the mist is moving through the holder 10. The mist recycler 21 directs the unused mist to a location before the holder 10. Preferably, the location is at the exit of the atomizer 4. The drain 22 can recycle liquid that has condensed from the mist during processing. The drain 22 pumps the liquid to a storage tank 23, or optionally directly back to the pump 3.

After the first mist comprising the first reactive component has sufficiently condensed on the ceramic green body, the apparatus can be used to coat the ceramic green body with a second fluid comprising the second reactive component. The second fluid comprising the reactive component can be atomized to form a second mist. The second mist can comprise the second reactive component and a carrier fluid. Alternatively, the second mist can consist essentially of the second reactive component if the neat reactive component can be formed into a mist. The second mist can be deposited on the ceramic green body by the method used for the first reactive component. To avoid having reactive components forming a solid or gel in the apparatus, the apparatus optionally can be cleaned before injecting the second reactive component. Alternatively, a second apparatus can be used to inject the second reactive component.

Advantageously, the disclosure provides for the use of the reactive compound and initiator, with or without a second component, that is, the fluid can consist essentially of the reactive compound without a carrier gas or liquid. For example, an epoxy resin typically can be reacted with an amine compound to form a polymer. Benzyl alcohol can be used to increase the reaction rate. The methods of the disclosure permit the addition of benzyl alcohol so that cure times can decrease, for example, from more than twenty-four hours to less than about three hours. At 100° C., benzyl alcohol can decrease reaction time by about three-fold, for example, from about 45 minutes to about 15 minutes. In embodiments, the method does not require mixing of components so that passivating with neat materials is possible. Raw materials can be purchased or provided neat, and used directly.

### EXAMPLE 1

A first 2″×6″ aluminum titanate filter (Filter A) was placed into a 2⅛″ diameter polymethyl methacrylate (PMMA) pipe. The filter was fitted with a rubber gasket so that any vapors introduced into the tube are forced to go through the filter. A fog generator (MiniFog Portable Fog Machine from American DJ) was connected to the PMMA pipe. The fog machine was filled with an amine solution consisting of 81 wt. % triethylene glycol diamine, 9 wt. % benzyl alcohol, and 10 wt. % water. The amine solution comprised a first part of a standard two-part epoxy composition. The fog machine produced a fog of the amine solution and the fog was passed down to the PMMA tube to the filter. In time, the desired weight of amine solution condensed on the filter.

A second fog machine was filled with an epoxy solution. The solution comprised 90 wt. % ethylene glycol diglycidyl ether (Erisys EGDGE from CVC Specialty Chemicals, Inc.) and 10 wt. % water. The epoxy solution comprised a second part of a standard two-part epoxy composition. A fog of the epoxy solution was condensed on the filter similarly to the amine solution. The filter was placed into a 100° C. forced-air oven for two hours to cure and dry the epoxy polymer product.

A second filter (Filter B) and third filter (Filter C) were provided. Both were identical to the first filter before treatment with the method of the disclosure. Filter B was not passivated with the epoxy. Filter C was passivated using a traditional immersion and blowout method. Filter B and C were dried at 100° C. in a forced air oven for two hours. The three filters were weighed, wash-coated with an alumina suspension, dried, and calcined to 550° C. The CTE was determined for each filter.

An acceptable bulk CTE is less than 15×10⁻⁷/° C. Filter B, the unpassivated filter, had a CTE of 39.0×10⁻⁷/° C. Filter C had a CTE of 9.4×10⁻⁷/° C., and incorporated about 2 wt. % epoxy into the filter. Filter A had a CTE of 8.4×10⁻⁷/° C., and incorporated less than 1 wt. % epoxy into the filter. Filter A had a lower CTE than Filter C and required less epoxy.

### EXAMPLE 2

The PMMA pipe, gasket, and filter were set up according to Example 1. Neat 2-methyl-1,-5-diaminopentane (amine) and neat 1,4-butanediol diglycidyl ether (epoxy) were provided. A 60 psi atomizer was used to generate a mist of the amine; although, any method of atomizing the components is suitable. These include, for example, heat, vacuum, high shear, high pressure, vibration, ultrasound, sublimation, blowing extremely fme powders, etc. The amine mist was applied to a porous ceramic filter. The epoxy mist was subsequently applied to the same filter. The passivated filter was cured for 2 hours at 100° C. The bulk CTE of the filter was less than of 10×10⁻⁷/° C.

Numerous modifications and variations of the disclosure are possible. While this disclosure has described certain preferred embodiments, different variations, modifications, and additions to the invention will become evident to persons of ordinary skill in the art. All such modifications, variations, and additions are intended to be encompassed within the scope of this patent, which is limited only by the appended claims.

1.-18. (canceled)

19. A method for applying a polymer on a honeycomb porous ceramic article, the method comprising:
contacting at least one fluid to the honeycomb porous ceramic article to deposit at least a portion of the at least one fluid on the interior walls of the honeycomb porous ceramic article;
polymerizing the at least one fluid to form a polymer membrane on the interior walls of the honeycomb porous ceramic article;
wherein the at least one fluid is selected from the group consisting of an aerosol, a vapor, a fog, a mist, a smoke, or combinations thereof.

20. The method of claim 19, wherein the at least one fluid comprises the polymer and a carrier fluid.

21. The method of claim 19, wherein the at least one fluid comprises a reactive compound that forms a polymer.

22. The method of claim 21, wherein the reactive compound that forms a polymer is selected from the group consisting of polymers and copolymers of urethane, epoxy, urea-formaldehyde, vinyl, alkoxysilane, oxetane, aziridine, phenolics, vinyl ethers, vinyl ester, acrylate, methacrylate, acrylamide, styryl, allyl, vinyl amide, vinyl amine, maleimide, maleate, itaconate, crotonate, anhydride, polyester, polyamide, polyimide, polyether, carbodiimide and like compounds, or combinations thereof.

23. The method of claim 21, wherein the reactive compound comprises a first reactive component and a second reactive component that can react with the first reactive component to form the polymer.

24. The method of claim 23, wherein the first reactive component comprises an organic diamine and the second reactive component comprises an organic ether.

25. The method of claim 24, wherein the first reactive component comprises alkylene glycol diamine and the second reactive component comprises alkylene glycol diglycidyl ether.

26. The method of claim 23 wherein the reactive compound comprises a reactive component that forms a polymer and an initiator.

27. The method of claim 23, wherein contacting the honeycomb porous ceramic article and the at least one fluid comprises contacting the porous ceramic article with the first reactive component and then contacting the porous ceramic article with the second reactive component.

28. The method of claim 19 further comprising a step of heating the at least one fluid before it is directed to the article.

29. The method of claim 28 wherein the at least one fluid is a vapor which condenses on the interior walls of the honeycomb porous ceramic article.

30. The method of claim 19 wherein the polymerizing step comprises heating the honeycomb porous ceramic article.

31. The method of claim 29 wherein the polymerizing step comprises heating the honeycomb porous ceramic article having the condensed fluid on the interior walls of the honeycomb porous ceramic article.

32. The method of claim 29 wherein when the condensed fluid polymerizes, it coalesces to form a continuous polymeric layer on the interior walls of the honeycomb porous ceramic article.

33. The method of claim 23, wherein contacting the honeycomb porous ceramic article and the at least one fluid comprises:
contacting the first reactive component and the honeycomb porous ceramic article to deposit at least a portion of the first reactive component on the honeycomb porous ceramic article; and
contacting the second reactive component and the honeycomb porous ceramic article to react a portion of the second reactive component and the first reactive component.

34. The method of claim 19, wherein the step of contacting at least one fluid to the honeycomb porous ceramic article to deposit at least a portion of the at least one fluid on the interior walls of the honeycomb porous ceramic article further comprises contacting the honeycomb porous ceramic article with a second fluid.

35. The method of claim 34 wherein the second fluid comprises a first reactive component and a second reactive component that can react with the first reactive component to form a second polymeric layer on the interior walls of the honeycomb porous ceramic article.

36. An apparatus for applying a polymer to a honeycomb porous ceramic article comprising:
a holder to hold the honeycomb porous ceramic article; and
an aerosolizer to produce a suspension of a fluid comprising at least one reactive component, the aerosolizer conveys the suspension to the holder.

37. The apparatus of claim 36, wherein the aerosolizer includes a nebulizer and a homogenizer.

38. The apparatus of claim 36 wherein the aerosolizer produces an aerosol, a vapor, a fog, a mist, a smoke, or combinations thereof.
